(19) United States
(12) Patent Application Publication
(10) Pub. No.: US 2026/0150452 A1
(43) Pub. Date: May 28, 2026

(54) LIGHT-EMITTING DEVICE

(71) Applicant: NICHIA CORPORATION, Anan-shi (JP)

(72) Inventors: Shinichi DAIKOKU, Tokushima-shi (JP); Takehiro SAGAWA, Okaya-shi (JP)

(73) Assignee: NICHIA CORPORATION, Anan-shi (JP)

(21) Appl. No.: 19/393,569

(22) Filed: Nov. 19, 2025

(30) Foreign Application Priority Data
Nov. 22, 2024 (JP) 2024-204024

(51) Int. Cl. H10H 20/858; H10H 20/831; H10H 20/841; H10H 20/857

(52) U.S. Cl. CPC H10H 20/8585; H10H 20/831; H10H 20/841; H10H 20/857

(57) ABSTRACT

A light-emitting device includes first and second conductive members, first and second bonding members, and a light-emitting element thereon and extending over the conductive members. The light-emitting element includes a light-emitting portion, first and second electrodes on a lower surface thereof, and a light-reflective covering member covering the conductive members, the bonding members, and the light-emitting element with lower surfaces of the conductive members exposed. The first electrode includes a first portion contacting the light-emitting portion and the first bonding member, and a second portion closer to the second electrode than the first portion and contacting the light-emitting portion. The second portion has a lower surface above that of the first portion. In cross-section, a thickness of the second portion is greater than the light-emitting portion, and a first distance between the second portion and the second electrode is shorter than a second distance between the conductive members.

### CROSS-REFERENCE TO RELATED APPLICATION

This application claims priority to Japanese Patent Application No. 2024-204024, filed on November 22, 2024, the disclosure of which is hereby incorporated by reference in its entirety.

### TECHNICAL FIELD

The present disclosure relates to a light-emitting device.

### BACKGROUND

Japanese Patent Publication No. 2003-86453 describes a mounting structure for an electrical element, in which the mounting structure includes a first lead frame and a second lead frame apart from and facing each other, and an electrical element mounted on one surface of the first lead frame and one surface of the second lead frame with a conductive adhesive in a state of straddling the first lead frame and the second lead frame.

### SUMMARY

Embodiments of the present disclosure can advantageously improve heat dissipation of a light-emitting device.

A light-emitting device according to an embodiment of the present disclosure includes: a first conductive member; a second conductive member separated from the first conductive member in a first direction; a first bonding member disposed on an upper surface of the first conductive member; a second bonding member disposed on an upper surface of the second conductive member; a light-emitting element disposed on the first bonding member and the second bonding member, and extending over the first conductive member and the second conductive member, the light-emitting element including a light-emitting portion, and first and second electrodes disposed on a lower surface of the light-emitting portion and separated from each other in the first direction; and a light-reflective covering member covering the first conductive member, the second conductive member, the first bonding member, the second bonding member, and the light-emitting element in such a manner that a lower surface of the first conductive member and a lower surface of the second conductive member are exposed, in which the first electrode includes a first portion in contact with the light-emitting portion and the first bonding member, and a second portion located closer to the second electrode relative to the first portion, and in contact with the light-emitting portion, the second portion having a lower surface located above a lower surface of the first portion, and in a cross-sectional view, a thickness of the second portion of the first electrode is greater than a thickness of the light-emitting portion, and a first distance in the first direction between the second portion of the first electrode and the second electrode is shorter than a second distance in the first direction between the first conductive member and the second conductive member.

According to embodiments of the present disclosure, heat dissipation of the light-emitting device can be improved.

### BRIEF DESCRIPTION OF DRAWINGS

FIG. 1 is a schematic top view illustrating a light-emitting device according to an embodiment.

FIG. 2 is a schematic cross-sectional view illustrating the light-emitting device taken along line II-II in FIG. 1.

FIG. 3 is a partial cross-sectional view of the light-emitting device, enlarging a region III illustrated in FIG. 2.

FIG. 4 is a partial cross-sectional view of the light-emitting device, illustrating another configuration example of a first bonding member included in the light-emitting device.

FIG. 5 is a partial cross-sectional view of the light-emitting device, enlarging a region V illustrated in FIG. 2.

FIG. 6 is a schematic top view illustrating a light-emitting device according to a modified example of the embodiment.

FIG. 7 is a schematic cross-sectional view illustrating the light-emitting device taken along line VII-VII of FIG. 6.

### DETAILED DESCRIPTION

Light-emitting devices according to embodiments of the present disclosure are described in detail below with reference to the drawings. However, the following embodiments are examples of light-emitting devices for embodying the technical concept of the embodiments, and the present disclosure is not limited to the following embodiments. Dimensions, materials, shapes, relative arrangements, or the like of constituent members described in the embodiments are not intended to limit the scope of the present disclosure thereto, unless otherwise specified, and are merely exemplary. Note that the sizes, positional relationship, or the like of members illustrated in the drawings may be exaggerated for clarity of description. In addition, in the following description, members having the same terms and reference characters represent the same or similar members, and detailed description of these members is omitted as appropriate. As a cross-sectional view, an end view illustrating only a cut surface may be used.

In the following drawings, directions may be indicated by an X axis, a Y axis, and a Z axis. The X axis, the Y axis, and the Z axis are orthogonal to each other. For example, in the present specification, the X-axis direction may be referred to as a "first direction X", the Y-axis direction may be referred to as a "second direction Y", and the Z-axis direction may be referred to as a "third direction Z". The direction in the X-axis direction toward which the arrow is pointed is referred to as a +X side, and the opposite direction to the +X side is referred to as a -X side. The direction in the Y-axis direction toward which the arrow is pointed is referred to as a +Y side, and the opposite direction to the +Y side is referred to as a -Y side. The direction in the Z-axis direction toward which the arrow is pointed is referred to as an upward direction or +Z side, and the opposite direction to the upward direction or the +Z side is referred to as a downward direction or -Z side.

The term "top view" used in the embodiment refers to viewing an object from the +Z side. However, this does not limit the orientation of the light-emitting device during use, and the orientation of the light-emitting device may be any chosen orientation. In the embodiments, a surface on the +Z side (that is, a surface of an object when viewed from the +Z side) is referred to as an "upper surface", and a surface on the -Z side (that is, a surface of an object when viewed from the -Z side) is referred to as a "lower surface".

In the present disclosure, a polygon such as a rectangle is referred to as a polygon, including a shape with chamfered or otherwise processed corners of a polygon, unless otherwise specified. A shape obtained by processing not only the corners (that is, the ends of a side) but also an intermediate portion of the side is also referred to as a polygon. That is, any shape partially processed while leaving its base polygonal shape is included in the interpretation of the "polygon" described in the present disclosure.

The term "to dispose" is not limited to cases of direct contact, but also includes cases of indirect disposing, e.g., through other members. The term “on” in the present disclosure encompasses both a configuration in which a member is disposed directly on and in contact with another member and a configuration in which a member is disposed on another member with a space or an intervening member interposed therebetween. The term “cover” in the present disclosure encompasses both a configuration in which a member directly covers and in contact with another member and a configuration in which a member covers another member with a space or an intervening member interposed therebetween.

### Embodiment

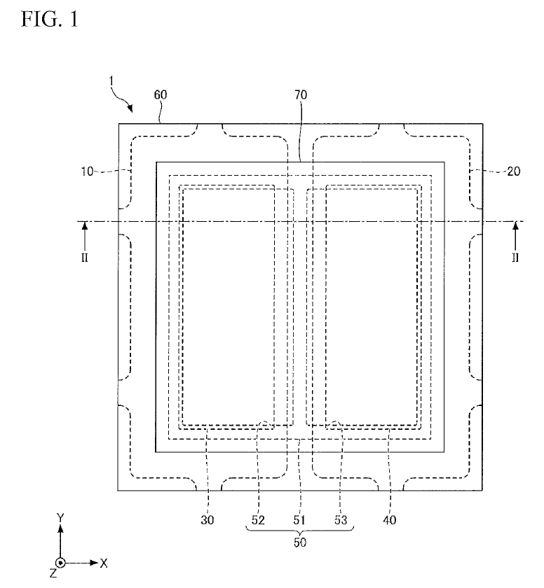

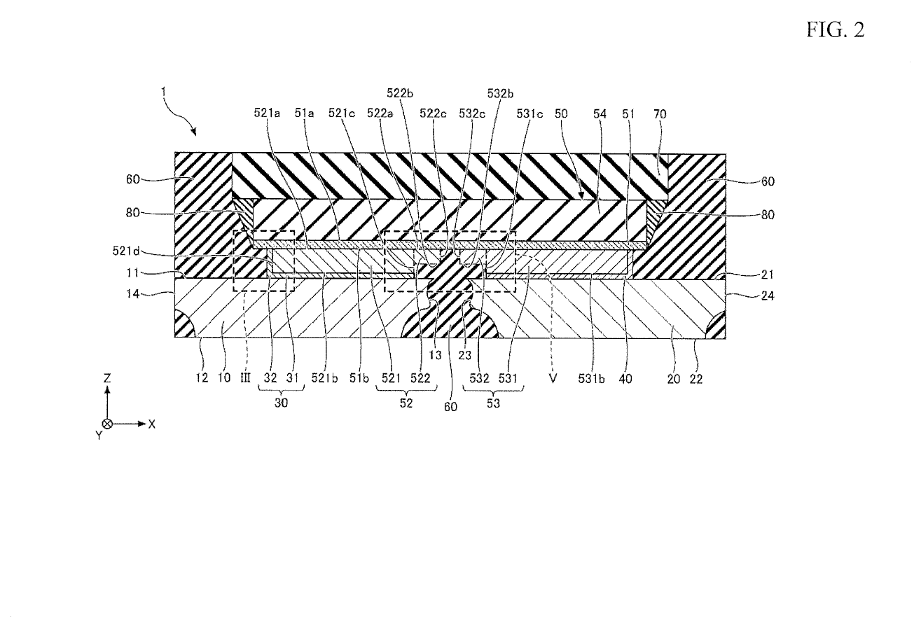

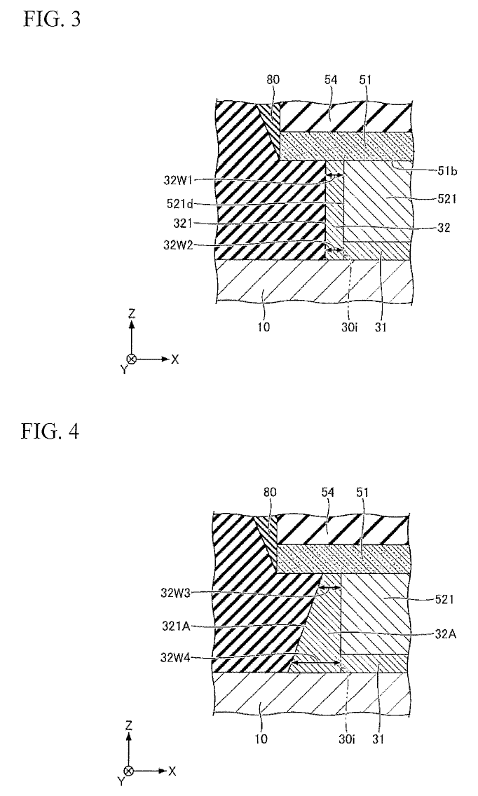

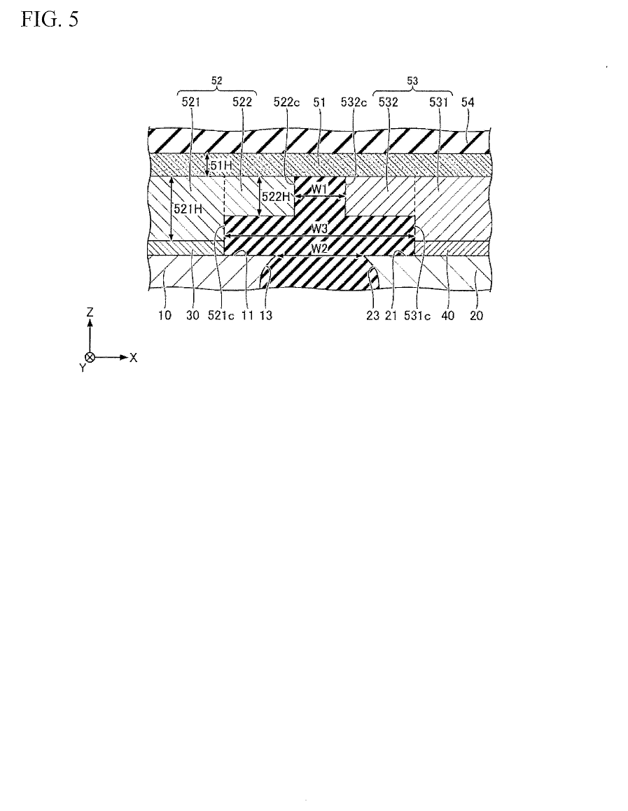

A configuration example of a light-emitting device 1 according to an embodiment will be described with reference to FIGS. 1 to 5. FIG. 1 is a schematic top view illustrating the light-emitting device 1 according to the embodiment. FIG. 2 is a schematic cross-sectional view illustrating the light-emitting device 1 taken along line II-II in FIG. 1. FIG. 3 is a partial cross-sectional view of the light-emitting device 1, enlarging a region III illustrated in FIG. 2. FIG. 4 is a partial cross-sectional view of the light-emitting device 1, illustrating another configuration example of a first bonding member 30 included in the light-emitting device 1. FIG. 5 is a partial cross-sectional view of the light-emitting device 1, enlarging a region V illustrated in FIG. 2.

The light-emitting device 1 illustrated in FIGS. 1 and 2 includes a first conductive member 10, a second conductive member 20, a first bonding member 30, a second bonding member 40, a light-emitting element 50, and a covering member 60. In the example illustrated in FIGS. 1 and 2, the light-emitting device 1 further includes a light-transmissive member 70 and a light guide member 80.

In the example illustrated in FIG. 1, the light-emitting device 1 has a rectangular shape in top view. In the example illustrated in FIGS. 1 and 2, the light-emitting device 1 includes two conductive members including the first conductive member 10 and the second conductive member 20. However, the light-emitting device 1 can include three or more conductive members. In the example illustrated in FIGS. 1 and 2, the first conductive member 10 is disposed on the -X side, and the second conductive member 20 is disposed on the +X side. The positional relationship between the first conductive member 10 and the second conductive member 20 in the first direction X can be reversed.

As illustrated in FIG. 2, the light-emitting element 50 includes a light-emitting portion 51, a first electrode 52, and a second electrode 53 separated from the first electrode 52 in the first direction X. The first electrode 52 and the second electrode 53 are disposed on a lower surface 51b of the light-emitting portion 51. The first electrode 52 includes a first portion 521 and a second portion 522, The first portion 521 is in contact with the light-emitting portion 51 and the first bonding member 30. The second portion 522 is located closer to the second electrode 53 relative to the first portion 521, and in contact with the light-emitting portion 51. A lower surface 522b of the second portion 522 is located at a higher level than a lower surface 521b of the first portion 521.

As illustrated in FIG. 5, in a cross-sectional view, a thickness 522H of the second portion 522 of the first electrode 52 is greater than a thickness 51H of the light-emitting portion 51. In the cross-sectional view, a first distance W1 between the second portion 522 of the first electrode 52 and the second electrode 53 in the first direction X is shorter than a second distance W2 between the first conductive member 10 and the second conductive member 20 in the first direction X. The light-emitting device 1 can reduce the possibility of a short circuit between the first conductive member 10 and the second conductive member 20, while efficiently releasing heat generated in the light-emitting portion 51 toward the first conductive member 10 and the second conductive member 20 via the second portion 522.

In a region that is located on the lower surface of the light-emitting portion 51 and is in contact with the first electrode 52 and the second electrode 53, the heat generated in the light-emitting portion 51 can be dissipated easily through the first electrode 52 and the second electrode 53. In contrast, in a region that is located on the lower surface of the light-emitting portion 51 and located between the first electrode 52 and the second electrode 53, the heat generated in the light-emitting portion 51 is less likely to be dissipated through the first electrode 52 and the second electrode 53. Because the first distance W1 between the second portion 522 of the first electrode 52 and the second electrode 53 in the first direction X is shorter than the second distance W2 between the first conductive member 10 and the second conductive member 20 in the first direction X, the region on the lower surface of the light-emitting portion 51 in which heat generated in the light-emitting portion 51 is less likely to be dissipated can be reduced. Accordingly, the heat dissipation of the light-emitting device 1 can be improved.

In the present specification, the term "thickness" refers to a distance in the third direction Z. In the present specification, the term "first distance W1" refers to a shortest distance between the second portion 522 and the second electrode 53 in the example illustrated in FIG. 5. In the example illustrated in FIG. 5, the first distance W1 corresponds to a shortest distance between a second inner lateral surface 522c of the second portion 522 and a fourth inner lateral surface 532c of a fourth portion 532 of the second electrode 53. In the example illustrated in FIG. 5, the term "second distance W2" refers to a shortest distance between the first conductive member 10 and the second conductive member 20. In the example illustrated in FIG. 5, the second distance W2 corresponds to a distance between an inner end portion of an upper surface 11 of the first conductive member 10 and an inner end portion of an upper surface 21 of the second conductive member 20.

Members constituting the light-emitting device 1 will be described below.

First Conductive Member 10 and Second Conductive Member 20

The first conductive member 10 and the second conductive member 20 are conductive members for supplying power to the light-emitting element 50. In the example illustrated in FIGS. 1 and 2, each of the first conductive member 10 and the second conductive member 20 is a plate-shaped member patterned into a predetermined shape. An upper surface of each of the first conductive member 10 and the second conductive member 20 is a flat surface and is parallel to the first direction X and the second direction Y.

Each of the first conductive member 10 and the second conductive member 20 includes a base body and a plating layer disposed on the surface of the base body. Examples of the material constituting the base body include copper (Cu), aluminum (Al), silver (Ag), gold (Au), zinc (Zn), chromium (Cr), tungsten (W), cobalt (Co), nickel (Ni), rhodium (Rh), ruthenium (Ru), and alloys thereof. The base body can contain a nonmetal such as silicon (Si) or phosphorus (P) as a trace element. The base body can have a single-layer structure composed of any of these metals or an alloy thereof, or can have a layered structure.

The plating layer is preferably formed of a material having a higher reflectance than the base body. Examples of the material constituting the plating layer include Ni, Ag, Au, platinum (Pt), palladium (Pd), Al, W, molybdenum (Mo), Ru, and Rh. The plating layer can have a single-layer structure composed of any of these metals or a layered structure. Examples of the plating layer having the layered structure include Ni/Pd/Au (that is, a plating layer in which Ni, Pd, and Au layers are stacked in this order from the base body side), Ni/Pt/Au (that is, a plating layer in which Ni, Pt, and Au layers are stacked in this order from the base body side), and Ni/Au/Ag (that is, a plating layer in which Ni, Au, and Ag layers are stacked in this order from the base body side).

As illustrated in FIG. 2, the first conductive member 10 has the upper surface 11, a lower surface 12 located opposite to the upper surface 11 in the third direction Z, and a plurality of lateral surfaces located between the upper surface 11 and the lower surface 12 in the third direction Z. Among the plurality of lateral surfaces, a first lateral surface 13 is a lateral surface located closer to the second conductive member 20, and a second lateral surface 14 is a lateral surface located opposite to the first lateral surface 13 in the first direction X.

In the example illustrated in FIG. 2, the first lateral surface 13 has two curved surfaces recessed toward the -X side. A curved surface of the two curved surfaces, which is located on the -Z side, is recessed most toward the -X side at a point located on the -X side relative to a point at which a curved surface of the two curved surfaces, located on the +Z side, is recessed most toward the -X side. This increases the distance in the first direction X between the lower surface 12 of the first conductive member 10 and a lower surface 22 of the second conductive member 20. As a result, when the light-emitting device 1 is mounted on a mounting substrate using an adhesive member, the adhesive member disposed on the first conductive member 10, and the adhesive member disposed on the second conductive member 20 are less likely to come into contact each other, whereby the possibility of a short circuit can be reduced. The first lateral surface 13 is not limited to the one having two curved surfaces. For example, the first lateral surface 13 can be formed of one surface such as a perpendicular surface perpendicular to the lower surface 12 or an inclined surface inclined with respect to the lower surface 12. The first lateral surface 13 can be constituted by three surfaces including a first surface located on the +Z side of the first lateral surface 13 and perpendicular or inclined to the upper surface 11, a second surface located on the -Z side of the first lateral surface 13 and perpendicular or inclined to the lower surface 12, and a third surface connecting the first surface and the second surface.

The second conductive member 20 is separated from the first conductive member 10 in the first direction X. Similarly to the first conductive member 10, the second conductive member 20 can also have the upper surface 21, the lower surface 22, and a plurality of lateral surfaces located between the upper surface 21 and the lower surface 22 in the third direction Z. Among the plurality of lateral surfaces, a third lateral surface 23 is a lateral surface located closer to the first conductive member 10 and facing the first lateral surface 13 of the first conductive member 10, and a fourth lateral surface 24 is a lateral surface located opposite to the third lateral surface 23 in the first direction X. The rest of the configuration of the second conductive member 20 can be the same as or similar to that of the first conductive member 10. Therefore, the description of the rest of the configuration of the second conductive member 20 will be omitted.

First Bonding Member 30 and Second Bonding Member 40

The first bonding member 30 bonds the first conductive member 10 and the first electrode 52 of the light-emitting element 50. The first conductive member 10 and the first electrode 52 are bonded via the first bonding member 30, so that the first conductive member 10 and the first electrode 52 are electrically connected.

The first bonding member 30 is disposed on the upper surface 11 of the first conductive member 10. In the example illustrated in FIG. 2, the first electrode 52 of the light-emitting element 50 includes the first portion 521 and the second portion 522 located closer to the second electrode 53 relative to the first portion 521. The first portion 521 has the lower surface 521b, a first inner lateral surface 521c, and an outer lateral surface 521d. The second portion 522 has the lower surface 522b. In this case, the first bonding member 30 covers the lower surface 521b and the outer lateral surface 521d of the first portion 521 of the first electrode 52. In other words, the first bonding member 30 includes an inner portion 31 located between the first conductive member 10 and the first portion 521 in the third direction Z, and an outer portion 32 covering the outer lateral surface 521d of the first portion 521. The boundary between the inner portion 31 and the outer portion 32 is a virtual straight line 30i extending downward from the lower end of the outer lateral surface 521d of the first portion 521 of the first electrode 52 illustrated in FIG. 3.

In the example illustrated in FIG. 2, the first bonding member 30 does not cover the first inner lateral surface 521c of the first portion 521 and the lower surface 522b of the second portion 522. In other words, the first inner lateral surface 521c of the first portion 521 and the lower surface 522b of the second portion 522 are exposed from the first bonding member 30. This can reduce the possibility for the first bonding member 30 to come into contact with the second electrode 53 and/or the second conductive member 20 through the second portion 522 of the first electrode 52, thereby reducing the possibility of occurrence of a short circuit. In view of reducing the possibility of occurrence of a short circuit between the first electrode 52 and the second electrode 53, preferably the first bonding member 30 does not cover the second inner lateral surface 522c of the second portion 522 located closer to the second electrode 53.

In the example illustrated in FIG. 3, the outer portion 32 of the first bonding member 30 is in contact with the lower surface 51b of the light-emitting portion 51 of the light-emitting element 50. This can further improve the heat dissipation of the light-emitting device 1. The outer portion 32 of the first bonding member 30 is not limited to being in contact with the lower surface 51b of the light-emitting portion 51 of the light-emitting element 50, and may not be in contact with the lower surface 51b of the light-emitting portion 51. When the outer portion 32 of the first bonding member 30 is not in contact with the lower surface 51b of the light-emitting portion 51, a stress applied to the light-emitting portion 51 from the first bonding member 30 can be reduced, whereby the possibility for the light-emitting portion 51 to be damaged can be reduced.

In the example illustrated in FIG. 3, a width 32W1 in the first direction X in the region of the outer portion 32 closer to the light-emitting portion 51 is equal to a width 32W2 in the first direction X in the region of the outer portion 32 closer to the first conductive member 10. For example, an outer surface 321 of the outer portion 32 is a perpendicular surface perpendicular to the upper surface of the first conductive member 10. When compared to a case, which will be described later, in which the outer surface 321 of the outer portion 32 is inclined with respect to the upper surface of the first conductive member 10, the stress applied to the light-emitting portion 51 from the first bonding member 30 can be reduced, and the possibility for the light-emitting portion 51 to be damaged can be reduced. Conceivably, this is because, when the case in which the outer surface 321 of the outer portion 32 is a perpendicular surface perpendicular to the upper surface of the first conductive member 10 is compared with the case in which the outer surface 321 of the outer portion 32 is inclined with respect to the upper surface of the first conductive member 10, the volume of the outer portion 32 is smaller when the outer surface 321 of the outer portion 32 is the perpendicular surface, provided that the contact area between the outer portion 32 and the light-emitting portion 51 is the same in both the cases.

In contrast, in the example illustrated in FIG. 4, a width 32W3 in the first direction X in the region of an outer portion 32A closer to the light-emitting portion 51 is shorter than a width 32W4 in the first direction X in the region of the outer portion 32A closer to the first conductive member 10. For example, an outer surface 321A of the outer portion 32A is inclined with respect to the upper surface of the first conductive member 10. Because heat generated in the light-emitting portion 51 travels to the -Z side while spreading to the -X side, the heat generated in the light-emitting portion 51 can be efficiently released toward the first conductive member 10 in the configuration in which the outer surface 321A of the outer portion 32A is inclined with respect to the upper surface of the first conductive member 10 of the first electrode 52.

When inclined with respect to the upper surface of the first conductive member 10, the outer surface 321A of the outer portion 32A is constituted by one inclined surface in the example illustrated in FIG. 4. However, the configuration is not limited to this example, and the outer surface 321A of the outer portion 32A can be constituted by a first perpendicular surface perpendicular to the upper surface of the first conductive member 10 in the region of the outer portion 32A closer to the first conductive member 10, a second perpendicular surface perpendicular to the lower surface of the light-emitting portion 51 in the region of the outer portion 32A closer to the light-emitting portion 51, and an inclined surface connecting the first perpendicular surface and the second perpendicular surface.

Examples of the material constituting the first bonding member 30 include alloys such as Au-Sn, Sn-Ag-Cu, Sn-Cu, Sn-Sb, Sn-Bi, Sn-In, Sn-Pb, and Ni-Sn.

As illustrated in FIG. 2, the second bonding member 40 bonds the second conductive member 20 and the second electrode 53 of the light-emitting element 50. The second conductive member 20 and the second electrode 53 are bonded via the second bonding member 40, so that the second conductive member 20 and the second electrode 53 are electrically connected. The second bonding member 40 is disposed on the upper surface 21 of the second conductive member 20. The second bonding member 40 can have a configuration that is the same as or similar to that of the first bonding member 30, except that the second bonding member 40 is disposed on the upper surface 21 of the second conductive member 20 and is in contact with the second electrode 53. Therefore, the description of the rest of the configuration of the second bonding member 40 will be omitted.

### Light-Emitting Element 50

The light-emitting element 50 is a semiconductor element that emits light by itself when voltage is applied. The light-emitting element 50 is, for example, a light-emitting diode (LED) chip. The light-emitting element 50 is disposed on the first bonding member 30 and the second bonding member 40, extending over the first conductive member 10 and the second conductive member 20. The light-emitting element 50 includes the light-emitting portion 51 and the first and second electrodes 52 and 53 having different polarities.

As illustrated in FIG. 2, the first electrode 52 is disposed between the light-emitting portion 51 and the first conductive member 10 in the third direction Z. Also, the second electrode 53 is disposed between the light-emitting portion 51 and the second conductive member 20 in the third direction Z.

In the example illustrated in FIG. 2, the light-emitting element 50 can further include an element substrate 54 disposed on the light-emitting portion 51. The element substrate 54 has light transmissivity. In the present specification, the term "light transmissivity" refers to a property with a transmittance of, for example, at least 60%, preferably 80% or more, to the light emitted from the light-emitting element 50. Examples of the material constituting the element substrate 54 include sapphire, spinel, glass, aluminum nitride, and silicon carbide. The light-emitting element 50 may not include the element substrate 54.

The light-emitting portion 51 can have an upper surface 51a, a lower surface 51b, and a plurality of lateral surfaces located between the upper surface 51a and the lower surface 51b in the third direction Z.

The light-emitting portion 51 includes a semiconductor layered body. The light-emitting portion 51 can further include, for example, two conductive layers disposed on the lower surface of the semiconductor layered body. The two conductive layers are separated from each other in the first direction X. One of the two conductive layers is disposed between the semiconductor layered body and the first electrode 52. The other of the two conductive layers is disposed between the semiconductor layered body and the second electrode 53.

The semiconductor layered body includes a first semiconductor layer, an active layer, and a second semiconductor layer. The first semiconductor layer, the active layer, and the second semiconductor layer are layered in the third direction Z. The first semiconductor layer and the second semiconductor layer have different conductivity types. For example, when the first semiconductor layer is an n-type semiconductor layer, the second semiconductor layer is a p-type semiconductor layer. When the first semiconductor layer is a p-type semiconductor layer, the second semiconductor layer is an n-type semiconductor layer. One of the first semiconductor layer and the second semiconductor layer is electrically connected to the first electrode 52. The other of the first semiconductor layer and the second semiconductor layer is electrically connected to the second electrode 53. The active layer can have a single quantum well (SQW) structure, or can have a multi quantum well (MQW) structure including a plurality of well layers.

Each of the first semiconductor layer, the active layer, and the second semiconductor layer is a semiconductor layer formed of, for example, a nitride semiconductor. The nitride semiconductor includes, in its category, semiconductors having all compositions in which in a chemical formula of InₓAl_{y}Ga_{1 - x - y}N (0 ≤ x, 0 ≤ y, and x + y ≤ 1), composition ratios x and y are changed within their respective ranges.

The light emission peak wavelength of the active layer can be selected as appropriate according to the purpose. The active layer is configured to emit visible light or ultraviolet light, for example.

When the structure including the first semiconductor layer, the active layer, and the second semiconductor layer is one layered body, the light-emitting portion 51 can include a plurality of layered bodies. In this case, the plurality of layered bodies can be stacked successively in the third direction Z. A plurality of active layers included in the plurality of layered bodies can include well layers having different light emission peak wavelengths, or well layers having the same light emission peak wavelength.

The combination of the light emission peak wavelengths of the plurality of layered bodies can be selected as appropriate. For example, when the semiconductor layered body includes two layered bodies, examples of the combination of light emitted from the respective active layers of the layered bodies include a combination of blue light and blue light, a combination of green light and green light, a combination of red light and red light, a combination of ultraviolet light and ultraviolet light, a combination of ultraviolet light and blue light, a combination of blue light and green light, a combination of blue light and red light, and a combination of green light and red light. For example, when the semiconductor layered body includes three layered bodies, examples of the combination of light emitted from the respective active layers of the layered bodies include a combination of blue light, green light, and red light.

The first electrode 52 includes the first portion 521 and the second portion 522 located closer to the second electrode 53 relative to the first portion 521. In the example illustrated in FIG. 5, the first portion 521 and the second portion 522 are continuous. In addition, a thickness 521H of the first portion 521 in the third direction Z is greater than a thickness 522H of the second portion 522 in the third direction Z.

As illustrated in FIG. 2, the first portion 521 has an upper surface 521a in contact with the light-emitting portion 51, the lower surface 521b in contact with the first bonding member 30, and the first inner lateral surface 521c and the outer lateral surface 521d located between the upper surface 521a and the lower surface 521b in the third direction Z.

In the example illustrated in FIG. 2, the upper surface 521a and the lower surface 521b of the first portion 521 are flat surfaces and parallel to the first direction X and the second direction Y. The first inner lateral surface 521c is located between the lower surface 521b of the first portion 521 and the lower surface 522b of the second portion 522 in the third direction Z. In the example illustrated in FIG. 2, the first inner lateral surface 521c is a perpendicular surface perpendicular to the lower surface 521b of the first portion 521. The first inner lateral surface 521c can be an inclined surface, for example, inclined with respect to the lower surface 521b of the first portion 521. The inclined surface can be linear or curved in a cross-sectional view. When the first inner lateral surface 521c is the inclined surface, an angle formed by the lower surface 521b and the first inner lateral surface 521c of the first portion 521 is preferably 90 degrees or more. This can allow heat generated in the light-emitting portion 51 and transmitted to the second portion 522 to be released efficiently to the first portion 521. As a result, the heat dissipation of the light-emitting device 1 can further be improved.

In the example illustrated in FIG. 5, a third distance W3 in the first direction X between the first inner lateral surface 521c of the first portion 521 and the second electrode 53 is longer than the second distance W2 between the first conductive member 10 and the second conductive member 20 in the first direction X. In the present specification, the term "third distance W3" refers to the shortest distance between the first inner lateral surface 521c of the first portion 521 and the second electrode 53 in the example illustrated in FIG. 5. In the example illustrated in FIG. 5, in the cross-sectional view, the third distance W3 corresponds to the shortest distance between the first inner lateral surface 521c of the first portion 521 and a third inner lateral surface 531c of a third portion 531 of the second electrode 53.

Because the third distance W3 is longer than the second distance W2, the distance between the first inner lateral surface 521c of the first portion 521 and the first lateral surface 13 in the first direction X can be increased. This can reduce the possibility for the first bonding member 30 to wet and spread toward the second conductive member 20 and reach the first lateral surface 13 of the first conductive member 10. As a result, the possibility for the first bonding member 30 to come into contact with the second conductive member 20 and cause a short circuit can be reduced. This can also increase the area of the covering member 60 in contact with the upper surface of the first conductive member 10, thereby improving adhesion between the covering member 60 and the first conductive member 10.

The outer lateral surface 521d is located opposite to the first inner lateral surface 521c in the first direction X. The outer lateral surface 521d corresponds to the lateral surface of the first electrode 52 located furthest on the -X side. In the example illustrated in FIG. 2, the outer lateral surface 521d is a perpendicular surface perpendicular to the lower surface 521b of the first portion 521. The outer lateral surface 521d can be, for example, an inclined surface inclined with respect to the lower surface 521b of the first portion 521. The inclined surface can be linear or curved in a cross-sectional view.

In the example illustrated in FIG. 2, the second portion 522 has an upper surface 522a in contact with the light-emitting portion 51, the lower surface 522b located opposite to the upper surface 522a in the third direction Z, and the second inner lateral surface 522c located between the upper surface 522a and the lower surface 522b in the third direction Z.

In the example illustrated in FIG. 2, the upper surface 522a and the lower surface 522b of the second portion 522 are flat surfaces and are parallel to the first direction X and the second direction Y. The second inner lateral surface 522c corresponds to the lateral surface of the first electrode 52 located furthest on the +X side. In the example illustrated in FIG. 2, the second inner lateral surface 522c is a perpendicular surface perpendicular to the upper surface 522a of the second portion 522. The second inner lateral surface 522c can be, for example, an inclined surface inclined with respect to the upper surface 522a of the second portion 522.

In the example illustrated in FIG. 5, the thickness 522H of the second portion 522 in the third direction Z is greater than the thickness 51H of the light-emitting portion 51 in the third direction Z in the cross-sectional view. However, the thickness 522H of the second portion 522 of the first electrode 52 can be equal to or less than the thickness 51H of the light-emitting portion 51.

The thickness 522H of the second portion 522 is preferably in a range of 0.2 times to 0.9 times the thickness 521H of the first portion 521 in the third direction Z. When the thickness 522H of the second portion 522 is equal to or more than 0.2 times the thickness 521H of the first portion 521, the heat dissipation effect provided by the second portion 522 of the first electrode 52 can be obtained easily. When the thickness 522H of the second portion 522 is equal to or less than 0.9 times the thickness 521H of the first portion 521, the possibility for the first bonding member 30 to reach the second electrode 53 and/or the second conductive member 20 through the second portion 522 can be reduced. This can reduce the possibility for the first bonding member 30 to come into contact with the second electrode 53 and/or the second conductive member 20 and to cause a short circuit. The thickness 522H of the second portion 522 is more preferably in a range of 0.3 times to 0.8 times the thickness 521H of the first portion 521, and even more preferably in a range of 0.4 times to 0.7 times the thickness 521H of the first portion 521. This can further enhance the effect of improving heat dissipation by the second portion 522 of the first electrode 52, and the effect of reducing the possibility for the first bonding member 30 to come into contact with the second electrode 53 and/or the second conductive member 20, and to cause a short circuit.

Examples of the material constituting the first portion 521 and the second portion 522 include the metals and alloys listed as examples of the material constituting the first conductive member 10 and the second conductive member 20.

As illustrated in FIG. 2, the second electrode 53 can include the third portion 531 and the fourth portion 532. The third portion 531 is in contact with the light-emitting portion 51 and the second bonding member 40. The fourth portion 532 is located closer to the first electrode 52 relative to the third portion 531, and in contact with the light-emitting portion 51. A lower surface 532b of the fourth portion 532 can be located at a higher level than a lower surface 531b of the third portion 531.

A width of the third portion 531 in the first direction X can be the same as or different from the width of the first portion 521 in the first direction X. In the example illustrated in FIG. 5, the third distance W3 is greater than the second distance W2. This can increase the distance in the first direction X between the third inner lateral surface 531c of the third portion 531 and the third lateral surface 23. That is, the distance in the first direction X between the first inner lateral surface 521c of the first portion 521 and the first lateral surface 13 can be increased, and the distance in the first direction X between the third inner lateral surface 531c of the third portion 531 and the third lateral surface 23 can be increased. This can reduce the possibility for the first bonding member 30 on the first conductive member 10 to wet and spread toward the second conductive member 20, and the possibility for the first bonding member 30 to reach the first lateral surface 13, while reducing the possibility for the second bonding member 40 on the second conductive member 20 to wet and spread toward the first conductive member 10, and the possibility for the second bonding member 40 to reach the third lateral surface 23. As a result, in the third direction Z, a difference in thickness between the first bonding member 30 on the first conductive member 10 and the second bonding member 40 on the second conductive member 20 is reduced, and the inclination of the light-emitting element 50 with respect to the third direction Z can be reduced. The rest of the configuration of the third portion 531 can be the same as or similar to that of the first portion 521. Therefore, the description of the rest of the configuration of the third portion 531 will be omitted.

The width of the fourth portion 532 in the first direction X can be the same as or different from the width of the second portion 522 in the first direction X. The rest of the configuration of the fourth portion 532 can be the same as or similar to that of the second portion 522. Therefore, the description of the rest of the configuration of the fourth portion 532 will be omitted.

Because the second electrode 53 includes the fourth portion 532 located closer to the first electrode 52 relative to the third portion 531, the first distance W1 can be shortened compared to a configuration in which the second electrode 53 does not include the fourth portion 532. This can improve the heat dissipation of the light-emitting device 1.

The first electrode 52 can further include a fifth portion located between the first portion 521 and the second portion 522 in the first direction X. The fifth portion is in contact with the light-emitting portion 51, and has a lower surface located at a higher level than the lower surface 521b of the first portion 521 and at a lower level than the lower surface 522b of the second portion 522. When the first electrode 52 includes the fifth portion, the fifth portion is not covered with the first bonding member 30. Similarly, the second electrode 53 can further include a sixth portion located between the third portion 531 and the fourth portion 532 in the first direction X. The sixth portion can have a configuration that is the same as or similar to that of the fifth portion.

### Covering Member 60

The covering member 60 has light reflectivity. The covering member 60 covers the first conductive member 10, the second conductive member 20, the first bonding member 30, the second bonding member 40, and the light-emitting element 50 such that the lower surface 12 of the first conductive member 10 and the lower surface 22 of the second conductive member 20 are exposed. The lower surface 12 of the first conductive member 10 and the lower surface 22 of the second conductive member 20 are exposed from the covering member 60, so that heat generated in the light-emitting portion 51 is easily dissipated to the outside from the lower surfaces of the first conductive member 10 and the second conductive member 20.

As illustrated in FIG. 2, the covering member 60 covers the lateral surfaces of the light-emitting element 50. This can allow light emitted from the lateral surfaces of the light-emitting element 50 to be reflected toward the upper surface of the light-emitting element 50, thereby improving the light extraction efficiency of the light-emitting device 1. A portion of the covering member 60 is disposed between the first electrode 52 and the second electrode 53, and between the first conductive member 10 and the second conductive member 20 in the cross-sectional view. Accordingly, light emitted downward from the light-emitting element 50 is less likely to be absorbed by the first conductive member 10, the second conductive member 20, the first bonding member 30, and the second bonding member 40. As a result, the light extraction efficiency of the light-emitting device 1 can be improved.

The covering member 60 can have insulating properties. As illustrated in FIG. 2, the covering member 60 is disposed between the first electrode 52 and the second electrode 53, and between the first conductive member 10 and the second conductive member 20. This can reduce the possibility of occurrence of a short circuit between the first electrode 52 and the second electrode 53, and between the first conductive member 10 and the second conductive member 20.

A material constituting the covering member 60 is, for example, a thermosetting resin. Examples of the thermosetting resin include an epoxy resin, a modified epoxy resin, a silicone resin, a modified silicone resin, an acrylate resin, a polyester resin (for example, an unsaturated polyester resin), and an urethane resin. The covering member 60 can further include light-reflective particles. Examples of the light-reflective particles include inorganic particles of titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, and calcium silicate.

### Light-Transmissive Member 70

The light-transmissive member 70 is a member having light transmissivity, is disposed on the light-emitting element 50, and transmits light emitted from the light-emitting element 50 to the outside. The light-transmissive member 70 is covered by the covering member 60 such that the upper surface of the light-transmissive member 70 is exposed. Light emitted from the light-emitting element 50 and passing through the lateral surfaces of the light-transmissive member 70 is reflected by the covering member 60 toward the upper surface of the light-transmissive member 70.

The light-transmissive member 70 can contain a wavelength conversion material that can convert the wavelength of at least part of light from the light-emitting element 50. This facilitates color adjustment of the light-emitting device 1. One or a plurality of types of wavelength conversion material can be contained in the light-transmissive member 70. The light-transmissive member 70 can be constituted by the wavelength conversion material and a base material, or can be constituted by only the wavelength conversion material. When the light-transmissive member 70 is constituted by the wavelength conversion material and the base material, the wavelength conversion material can be contained in the base material, or can be disposed on the surface of the base material. When the wavelength conversion material is disposed on the surface of the base material, the wavelength conversion material can be disposed on a surface of the base material facing the light-emitting element 50. In addition, only the wavelength conversion material can be disposed on the surface of the base material, or a resin containing the wavelength conversion material can be disposed on the surface of the base material. As the wavelength conversion material, a phosphor can be used.

Examples of the material of the base material of the light-transmissive member 70 include an inorganic material, such as glass, ceramic, or sapphire, and an organic material, such as a resin or a hybrid resin containing one or more kinds of a silicone resin, a modified silicone resin, an epoxy resin, a modified epoxy resin, an acrylic resin, a phenol resin, and a fluorine resin.

Examples of the phosphor that can be used include an yttrium aluminum garnet phosphor (for example, Y₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a nitride phosphor such as a β-sialon phosphor (for example, (Si,Al)₃(O,N)₄:Eu), an α-sialon phosphor (for example, Ca(Si,Al)₁₂(O,N)₁₆:Eu), an SLA phosphor (for example, SrLiAl₃N₄:Eu), a CASN phosphor (for example, CaAlSiN₃:Eu), or an SCASN phosphor (for example, (Sr,Ca)AlSiN₃:Eu), a fluoride phosphor such as a KSF phosphor (for example, K₂SiF₆:Mn), a KSAF phosphor (for example, K₂(Si,Al)F₆:Mn), or an MGF phosphor (for example, 3.5MgO·0.5MgF₂·GeO₂:Mn), a phosphor having a perovskite structure (for example, CsPb(F,Cl,Br,I)₃), and a quantum dot phosphor (for example, CdSe, InP, AgInS₂, or AgInSe₂).

The light-transmissive member 70 can include a light scattering agent. Examples of the material of the light scattering agent include titanium oxide, silicon oxide, aluminum oxide, zinc oxide, magnesium oxide, zirconium oxide, yttrium oxide, calcium fluoride, magnesium fluoride, niobium pentoxide, barium titanate, tantalum pentoxide, barium sulfate, and glass.

The light-emitting device 1 is not limited to including the light-transmissive member 70, and may not include the light-transmissive member 70.

### Light Guide Member 80

The light guide member 80 is a member for bonding the light-emitting element 50 and the light-transmissive member 70. The light guide member 80 is disposed between the upper surface of the light-emitting element 50 and the lower surface of the light-transmissive member 70. The light guide member 80 further covers the lateral surfaces of the light-emitting portion 51. This allows the light guide member 80 to guide the light emitted from the lateral surfaces of the light-emitting element 50 to the light-transmissive member 70. As a result, the light extraction efficiency of the light-emitting device 1 can be improved. The light guide member 80 may not cover the lateral surfaces of the light-emitting portion 51.

In the example illustrated in FIG. 2, the light guide member 80 has a triangular cross-sectional shape with the width of the triangle in the first direction X increasing toward the upward direction. That is, the outer surface of the light guide member 80 in a cross-sectional view is a straight line. However, the outer surface of the light guide member 80 in a cross-sectional view can be a curved line.

As the light guide member 80, a resin material, for example, can be used. As the resin material, a resin material formed of a resin, a hybrid resin, or the like containing one or more kinds of a silicone resin, a modified silicone resin, an epoxy resin, a modified epoxy resin, an acrylic resin, and a fluororesin can be used.

In the light-emitting device 1, the light-transmissive member 70 is bonded with the light-emitting element 50 via the light guide member 80. However, there is no limitation thereto, and the light-transmissive member 70 can be directly bonded with the light-emitting element 50 without via the light guide member 80. When the light-transmissive member 70 is directly bonded with the light-emitting element 50, a direct bonding method by, for example, crimping, sintering, surface activation bonding, atomic diffusion bonding, or hydroxyl group bonding can be used.

### Modified Example

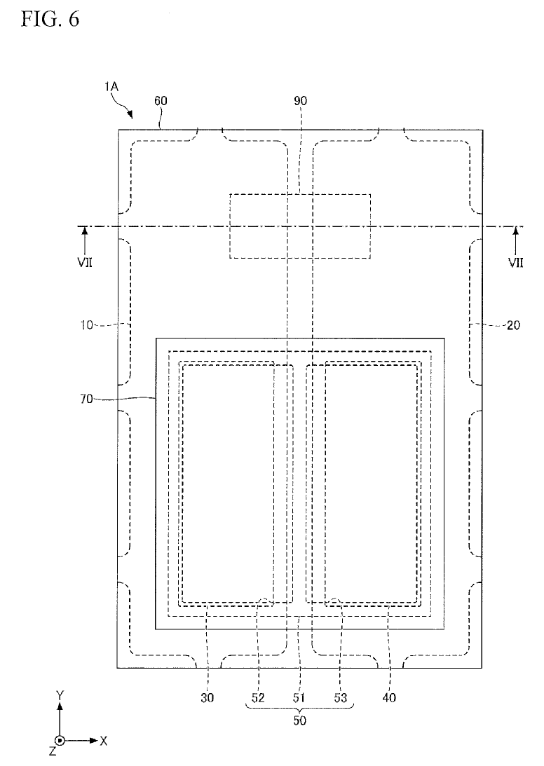

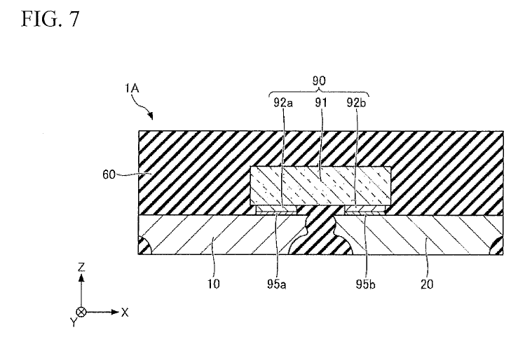

Referring to FIGS. 6 and 7, a configuration example of a light-emitting device 1A according to a modified example of the embodiment will be described. FIG. 6 is a schematic top view illustrating the light-emitting device 1A according to the modified example. FIG. 7 is a schematic cross-sectional view illustrating the light-emitting device 1A taken along line VII-VII in FIG. 6. In the modified example, the components that are the same as or similar to those of the embodiment described above will be denoted by the same reference characters and the description thereof will be omitted as appropriate.

As illustrated in FIG. 6, the light-emitting device 1A can further include a protective element 90. The protective element 90 and the light-emitting element 50 are connected in parallel. This can reduce the voltage load applied between the first electrode 52 and the second electrode 53 of the light-emitting element 50 by decreasing the resistance of the parallel circuit including the protective element 90 and bypassing the current when an excessive voltage load is applied to the light-emitting element 50. In the example illustrated in FIGS. 6 and 7, the protective element 90 is a Zener diode. However, the protective element 90 is not limited to the Zener diode, and can be another protective element such as a varistor.

In the example illustrated in FIG. 7, the protective element 90 includes an element portion 91 and electrodes 92a and 92b having different polarities. In the example illustrated in FIGS. 6 and 7, the protective element 90 straddles the first conductive member 10 and the second conductive member 20. The electrodes 92a and 92b are disposed on the lower surface of the element portion 91. The electrode 92a is bonded with the first conductive member 10 via a bonding member 95a. The electrode 92b is bonded with the second conductive member 20 via a bonding member 95b. However, the electrodes 92a and 92b can be disposed on the upper surface side of the element portion 91. In this case, the protective element 90 is disposed on one of the first conductive member 10 and the second conductive member 20. The electrode 92a is electrically connected to the first conductive member 10, for example, via a bonding wire. Similarly, the electrode 92b is electrically connected to the second conductive member 20, for example, via a bonding wire.

Although the preferred embodiments and the like have been described in detail above, the disclosure is not limited to the above-described embodiments and the like, various modifications and substitutions can be made to the above-described embodiments and the like without departing from the scope described in the claims.

What is claimed is:

1. A light-emitting device comprising:
a first conductive member;
a second conductive member separated from the first conductive member in a first direction;
a first bonding member disposed on an upper surface of the first conductive member;
a second bonding member disposed on an upper surface of the second conductive member; and
a light-emitting element comprising
a light-emitting portion,
a first electrode disposed on a lower surface of the light-emitting portion,
a second electrode disposed on the lower surface of the light-emitting portion and separated from the first electrode in the first direction, the light-emitting element being disposed on the first bonding member and the second bonding member, the light-emitting element straddling the first conductive member and the second conductive member, and
a light-reflective covering member covering the first conductive member, the second conductive member, the first bonding member, the second bonding member, and the light-emitting element in such a manner that a lower surface of the first conductive member and a lower surface of the second conductive member are exposed, wherein
the first electrode comprises
a first portion in contact with the light-emitting portion and the first bonding member, and
a second portion located closer to the second electrode relative to the first portion, the second portion being in contact with the light-emitting portion, the second portion having a lower surface located at a higher level than a lower surface of the first portion,
in a cross-sectional view, a thickness of the second portion is greater than a thickness of the light-emitting portion, and
a first distance in the first direction between the second portion and the second electrode is shorter than a second distance in the first direction between the first conductive member and the second conductive member.

2. The light-emitting device according to claim 1,
wherein the thickness of the second portion of the first electrode is in a range of 0.2 times to 0.9 times a thickness of the first portion of the first electrode.

3. The light-emitting device according to claim 1, wherein
the first portion has a first inner lateral surface located between the lower surface of the first portion and the lower surface of the second portion,
the first portion has an outer lateral surface located opposite to the first inner lateral surface,
the first bonding member covers the lower surface of the first portion and covers the outer lateral surface of the first portion, and
the first inner lateral surface of the first portion and the lower surface of the second portion are exposed from the first bonding member.

4. The light-emitting device according to claim 3, wherein
the first bonding member comprises
an inner portion located between the first portion and the first conductive member, and
an outer portion covering the outer lateral surface of the first portion, and
the outer portion is in contact with the light-emitting portion.

5. The light-emitting device according to claim 4, wherein
a width in the first direction in a region of the outer portion closer to the light-emitting portion is equal to a width in the first direction in a region of the outer portion closer to the first conductive member.

6. The light-emitting device according to claim 4, wherein
a width in the first direction in a region of the outer portion closer to the light-emitting portion is shorter than a width in the first direction in a region of the outer portion closer to the first conductive member.

7. The light-emitting device according to claim 3, wherein
a third distance in the first direction between the first inner lateral surface of the first portion and the second electrode is longer than the second distance in the first direction between the first conductive member and the second conductive member.

8. The light-emitting device according to claim 1, wherein
the second electrode comprises
a third portion in contact with the light-emitting portion and the second bonding member, and
a fourth portion located closer to the first electrode relative to the third portion, and the fourth portion being in contact with the light-emitting portion, the fourth portion having a lower surface located at a higher level than a lower surface of the third portion.

9. The light-emitting device according to claim 2, wherein
the first portion has a first inner lateral surface located between the lower surface of the first portion and the lower surface of the second portion,
the first portion has an outer lateral surface located opposite to the first inner lateral surface,
the first bonding member covers the lower surface of the first portion and covers the outer lateral surface of the first portion, and
the first inner lateral surface of the first portion and the lower surface of the second portion are exposed from the first bonding member.

10. The light-emitting device according to claim 9, wherein
the first bonding member comprises
an inner portion located between the first portion and the first conductive member, and
an outer portion covering the outer lateral surface of the first portion, and
the outer portion is in contact with the light-emitting portion.

11. The light-emitting device according to claim 10, wherein
a width in the first direction in a region of the outer portion closer to the light-emitting portion is equal to a width in the first direction in a region of the outer portion closer to the first conductive member.

12. The light-emitting device according to claim 10, wherein
a width in the first direction in a region of the outer portion closer to the light-emitting portion is shorter than a width in the first direction in a region of the outer portion closer to the first conductive member.

13. The light-emitting device according to claim 9, wherein
a third distance in the first direction between the first inner lateral surface of the first portion and the second electrode is longer than the second distance in the first direction between the first conductive member and the second conductive member.

14. The light-emitting device according to claim 2, wherein
the second electrode comprises
a third portion in contact with the light-emitting portion and the second bonding member, and
a fourth portion located closer to the first electrode relative to the third portion, and the fourth portion being in contact with the light-emitting portion, the fourth portion having a lower surface located at a higher level than a lower surface of the third portion.
